(19) United States
(12) Patent Application Publication
(10) Pub. No.: US 2009/0197354 A1
(43) Pub. Date: Aug. 6, 2009

(54) SYSTEM AND METHOD FOR MONITORING MANUFACTURING PROCESS

(75) Inventors: Tzu-Cheng Lin, Taipei City (TW); Yun-Zong Tian, Taichung County (TW); Chun-Chi Chen, Taipei City (TW); Yi-Feng Lee, Taoyuan County (TW)

Correspondence Address: QUINTERO LAW OFFICE, PC, 2210 MAIN STREET, SUITE 200, SANTA MONICA, CA, 90405, US

(73) Assignee: INOTERA MEMORIES, INC., Taoyuan (TW)

(21) Appl. No.: 12/144,488

(22) Filed: Jun. 23, 2008

(30) Foreign Application Priority Data
Feb. 5, 2008 (TW) TW97104542

(51) Int. Cl. H01L 21/66; G06T 11/20

(52) U.S. Cl. 438/14; 345/440; 257/E21.529

(57) ABSTRACT

A system and method for monitoring a manufacturing process are provided. A wafer is provided. Process parameters of a manufacturing machine are in-situ measured and recorded if the wafer is processed in the manufacturing machine. A wafer measured value of the wafer is measured after the wafer has been processed. The process parameters are transformed into a process summary value. A two dimensional orthogonal chart with a first axis representing the wafer measured value and a second axis representing the process summary value is provided. The two dimensional orthogonal chart includes a close-loop control limit. A visualized point representing the wafer measured value and the process summary value is displayed on the two dimensional orthogonal chart.

### CROSS REFERENCE TO RELATED APPLICATIONS

This Application claims priority of Taiwan Patent Application No. 097104542, filed on Feb. 5, 2008, the entirety of which is incorporated by reference herein.

### BACKGROUND OF THE INVENTION

1. Field of the Invention

The present invention relates to a system and method for monitoring a manufacturing process.

2. Description of the Related Art

Continuing advances in semiconductor manufacturing processes have resulted in semiconductor devices with precision features and/or higher degrees of integration manufactured by using higher level process control technologies. However, process degree variations for a wafer processed by a manufacturing machine can not be avoided. The process degree variations of the wafer may be caused by factors such as variations in, human operation, manufacturing machine, materials, manufacturing methods, environment, etc. Nevertheless, some process degree variations are acceptable. For example, such as, a slight process degree variation (gradual shifting) due to a decreasing concentration of a reaction solution or a greater process degree variation (more violent shifting) due to replacement of manufacturing machine parts during the regular maintenance process. Because the variations are foreknown, rarely influence product quality and can not be eliminated technically and economically, they are acceptable. However, some abnormal process degree variations are not acceptable. The abnormal process degree variations usually result from system issues (abnormal issues). In this case, the abnormal process degree variations should be avoided as they may greatly influence product quality. Due to the aforementioned, during the manufacturing process, engineers must monitor manufacturing machines, processes and products for process degree variations. Once the process degree variation is identified, engineers must efficiently locate the cause of the variation and make necessary adjustments or implement necessary measures in efforts to not negatively influence production yield. The efficient identification, cause and counter measures are accomplished by monitoring the process condition of manufacturing machines and/or processes.

A statistical process control (SPC) method is usually used for monitoring the process condition. After a wafer is processed by a manufacturing machine, the wafer is tested for a measured value of the wafer, such as film thickness, depth, etching rate, etc. The measured value is inputted into a run chart used for observing or analyzing the process condition over a period of time. A fault detection and classification (FDC) method is usually used for monitoring the manufacturing machine condition, to collect set data and practical data of the process parameters of the manufacturing machine.

However, despite the methods, because both methods are used independently of one another, the relationship between the processes and the manufacturing machines during the manufacturing process is not appropriately addressed or monitored. For example, physics theory dictates that the measured value of the processed wafer has a specific relationship with the manufacturing process of the manufacturing machines, such as conservation of mass or energy. Specifically, wafer film thickness deposited by a chemical vapor deposition process, often depends on the set temperature and time of the stable high temperature step of the manufacturing process. However, even if no variations are found in the stable high temperature step process and the measured value of the wafer is normal after the wafer has been processed in the manufacturing machine, the final electrical test of the product may still show variations or fail, due to abnormal conditions. The abnormal conditions occur due to the relationship between the processes and the manufacturing machine and are not monitored, wherein the measured value is shifted due to an abnormal temperature or time of a rising temperature step or falling temperature step. Thus, highlighting the importance for monitoring of the manufacturing process, of the relationship between the processes and the manufacturing machines, and the SPC method and the FDC method.

As a result, a system and method is needed for monitoring a manufacturing process by using the SPC method and the FDC method at the same time, so that the relationship between the processes and the manufacturing machines can be monitored, and production yield can be increased.

### BRIEF SUMMARY OF INVENTION

A detailed description is given in the following embodiments with reference to the accompanying drawings.

The invention provides a system for monitoring a manufacturing process. A two dimensional orthogonal chart with a first axis representing a measured value of a wafer and a second axis representing a process summary value of a manufacturing process of a manufacturing machine is provided. The two dimensional orthogonal chart includes a close-loop control limit. A visualized point is displayed on the two dimensional orthogonal chart, representing the wafer measured value and the process summary value.

The invention also provides a method for monitoring a manufacturing process. A wafer is provided. Process parameters of a manufacturing machine are in-situ measured and recorded if the wafer is processed in the manufacturing machine. A wafer measured value of the wafer is measured after the wafer has been processed. The process parameters are transformed into a process summary value. A two dimensional orthogonal chart with a first axis representing the wafer measured value and a second axis representing the process summary value is provided. The two dimensional orthogonal chart includes a close-loop control limit. A visualized point representing the wafer measured value and the process summary value is displayed on the two dimensional orthogonal chart.

Another embodiment of the method for monitoring the manufacturing process is provided. A wafer is provided. Process parameters of a manufacturing machine are in-situ measured and recorded if the wafer is processed in the manufacturing machine. A wafer measured value of the wafer is measured after the wafer has been processed. The process parameters are transformed into a process summary value. A two dimensional orthogonal chart with a first axis representing the wafer measured value and a second axis representing the process summary value is provided. The two dimensional orthogonal chart includes an elliptical control limit determined from the optimum wafer measured value and process summary value statistics obtained from previous manufacturing processes of the manufacturing machine. A visualized point representing the wafer measured value and the process summary value is displayed on the two dimensional orthogonal chart.

### BRIEF DESCRIPTION OF DRAWINGS

The present invention can be more fully understood by reading the subsequent detailed description and examples with references made to the accompanying drawings, wherein:

FIG. 1 is a flow chart illustrating the preferred embodiment of a method for monitoring a manufacturing process.

FIG. 2 illustrates a relationship of the wafers and the process parameters corresponding to the wafers of an embodiment of the invention.

FIG. 3 illustrates a process control chart according to an embodiment of the present invention.

FIG. 4 illustrates a control chart according to an embodiment of the present invention.

### DETAILED DESCRIPTION OF INVENTION

The following description is of the best-contemplated mode of carrying out the invention. This description is made for the purpose of illustrating the general principles of the invention and should not be taken in a limiting sense. The scope of the invention is best determined by reference to the appended claims.

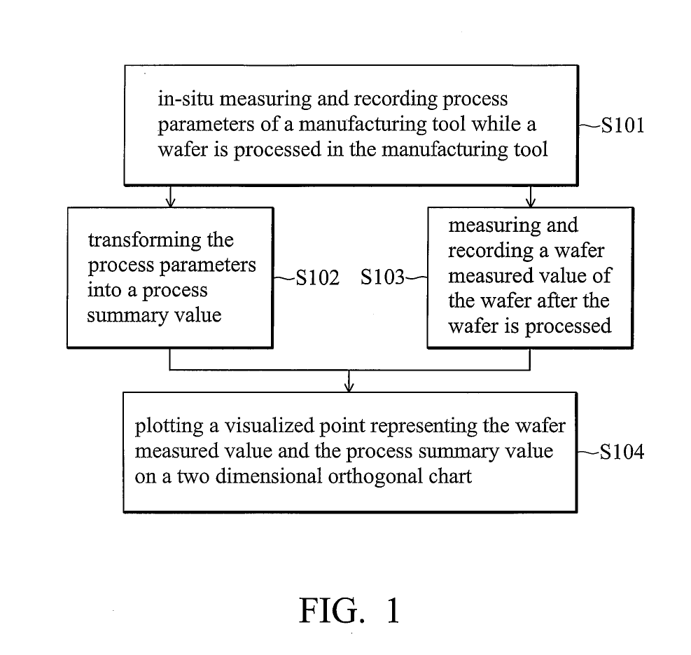

FIG. 1 is a flow chart illustrating the preferred embodiment of a method for monitoring a manufacturing process. For step S101, process parameters of a manufacturing machine are in-situ measured and recorded while a wafer is processed in the manufacturing machine. The process parameters, including temperature, pressure, flow rate, leakage rate, concentration, time, etc., may be recorded at a constant time interval.

Referring to FIG. 1, after the wafer has been processed in the manufacturing machine (step S101 completed), a measured value of the wafer is tested for step S103. In one embodiment, after a single wafer is processed in the manufacturing machine, measured value of the wafer is tested. In another embodiment, after one or a plurality of wafer lots is processed in the manufacturing machine, a measured value of a wafer, randomly chosen from the wafer lots or specifically chosen according to a specific position in the manufacturing machine, is tested. In other embodiments, after a wafer is processed in the manufacturing machine for a period of time or several runs, a measured value of the wafer is tested. The wafer measured value may include particle numbers, electric properties, flatness, etching rates, thicknesses, dosages, etc.

Referring to FIG. 1, after step S101 is completed and the process parameters are obtained, for step S102, the process parameters are transformed into a process summary value. In the preferred embodiment, the process parameters are transformed by using reference process parameters to obtain the process summary value corresponding to the process parameters. In one embodiment, the process parameters may include temperatures, pressure, flow rates, leakage rates, concentrations, time, and/or be measured and recorded during a same condition such as a specific step or time interval. For example, the process parameters may be implemented during the period of time it takes for the pressure of the manufacturing machine to reduce from an atmospheric pressure to a vacuum (the same condition). The process parameters may also be the maximum concentration or the minimum concentration of the etchant used for etching the wafer (the same condition). The process parameters can be measured and recorded during other manufacturing processes. The process parameters may be chosen based upon particularities of specific steps or time intervals. For example, a film thickness formed on a wafer by a chemical vapor deposition process and resulting measured value thereof, are particularly influenced by the time and the temperature of the stable high temperature heating step. The reference process parameters can be process parameters target values, or average values or optimum values calculated according to historical data of the process parameters.

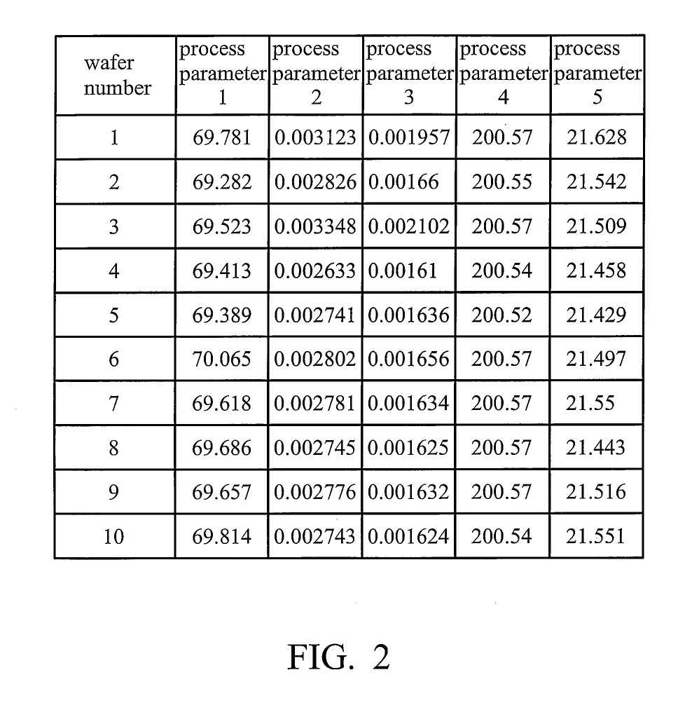

In the preferred embodiment, the transforming step S102 is performed by using a matrix associated with one or more wafers and the process parameters correspond to the respective wafers. FIG. 2 illustrates a relationship of the wafers and the process parameters corresponding to the wafers of an embodiment of the invention. In this embodiment, the process parameter 1 is a chamber heater temperature (° C.), the process parameter 2 is a gas (such as oxygen gas) flow (sccm), the process parameter 3 is a pumping pressure (torr), the process parameter 4 is a wall heater temperature (° C.), and the process parameter 5 is a gas (such as nitrogen gas) flow (sccm). In this embodiment, the transforming step S102 is performed by using a 10×5 or 5×10 matrix associated with the wafers and the process parameters related with the wafers. In one embodiment, the process summary value Z can be calculated by using the following equation:

Z=(α− α̅)^{T}S⁻¹(α− α̅)

In the equation, α=the matrix associated with the process parameters, α̅=the matrix associated with the reference process parameters, and S⁻¹ is the inverse correlation of the matrix. In another embodiment, the process summary value Z can be calculated by using the following equation:

$$Z = {( \frac{α - \overline{α}}{σ} )}^{T} {S}^{- 1} ( \frac{α - \overline{α}}{σ} )$$

In the equation, σ=the standard deviation calculated based on the reference process parameters. In addition to the equations described above, the process summary value Z may be calculated by using other appropriate equations.

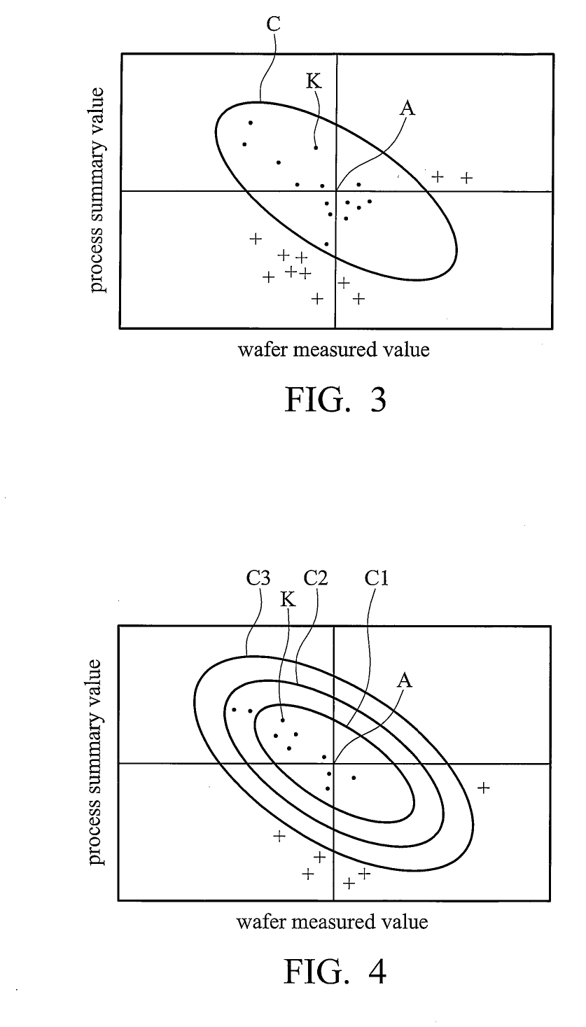

FIG. 3 illustrates a process control chart according to an embodiment of the present invention. The process control chart is a two dimensional orthogonal chart with a first (X) axis and a second (Y) axis perpendicular to one another. The first (X) axis relates to the wafer measured value, and the second (Y) axis relates to the process summary value. A visualized point is displayed on the process control chart. The visualized point represents the wafer measured value by the corresponding relation with the first (X) axis, and represents the process summary value by the corresponding relation with the second (Y) axis. In another embodiment, the second (Y) axis relates to the wafer measured value, and the first (X) axis relates to the process summary value. The visualized point can represent that the wafer measured value by the corresponding relation with the second (Y) axis, and represent the process summary value by the corresponding relation with the first (X) axis.

In the preferred embodiment, the process control chart has an elliptical control limit C as shown in FIG. 3. The elliptical control limit C can be determined from the previous (or historical) wafer measured value and process summary value statistics, obtained from the previous (or historical) manufacturing processes of the manufacturing machine. The elliptical control limit C can also be determined from the previous (or historical) optimum wafer measured value and process summary value statistics, obtained from the previous (or historical) optimum manufacturing processes of the manufacturing machine. Not limiting to the elliptical shape, in other embodiments, the control limit C can have other appropriate close-loop shapes. A target position A is placed at the center of the elliptical control limit C. The target position A, as shown in FIG. 3, represents the target (or optimum) wafer measured value of the first (or X) axis and the target (or optimum) process summary value of the second (or Y) axis. In another embodiment, the target position A represents the target (or optimum) process summary value of the first (or X) axis and the target (or optimum) wafer measured value of the second (or Y) axis. In one embodiment, the target position A can be placed at the inside of the control limit C or other appropriate positions, and is not limited to being placed at the center of the control limit C.

A process quality of the manufacturing machine can be determined according to the position of the visualized point K on the process control chart. If the visualized point K is close to the target position A, the process quality is determined to be good. On the contrary, if the visualized point K is far from the target position A, the process quality is determined to be bad. In other words, the manufacturing process is regarded as being an “under control” process if the visualized point K is inside of the control limit C, and the manufacturing process is regarded as being an “out of control” process if the visualized point K is outside of the control limit C. In one embodiment, if the visualized point K shifts from the target position A, the appropriate process parameters can be feed back to the manufacturing machine to control the process by a control system according to the wafer measured value or the process summary value. In one embodiment, if the visualized point K is outside of the control limit C, a warning action can be performed by the system. The warning action includes a warning signal, a warning sound, and shut down of the manufacturing machine. In one embodiment, the visualized points K distributed with a specific direction or location on the process control chart is most likely the result of the same or similar process parameter variation. Thus, a process control chart is used to monitor the wafer measured value and the process parameters at the same time. Specifically, a system and method is provided for monitoring a manufacturing process by using the wafer measured value and the process parameters at the same time, so that the relationship between the processes and the manufacturing machines can be monitored, and production yield can be increased.

The visualized point K can be represented as any shape and color on the process control chart. In one embodiment, the visualized points K located inside of the control limit C and outside of the control limit C are represented as different shapes as shown in FIG. 3. In another embodiment, the visualized points K located inside of the control limit C and outside of the control limit C are represented as different colors (not shown). The wafer measured value and the process summary value represented by the visualized point K may be shown by a side of the visualized point K. A notification signal, represented as a green, orange, red, or other colors to show the stability of the last process or recent processes of the manufacturing machine, may be displayed on the process control chart. The visualized point K located outside of the control limit C can be represented by the number of the wafer shown by the side of visualized point K. The process control can have other appropriate functions which may be conveniently used to monitor the manufacturing process.

FIG. 4 illustrates a control chart according to an embodiment of the present invention. Similar description of FIG. 4 that was described and shown in detail for FIG. 3 will not be described in detail again. The process control chart has a control limit of one sigma standard deviation C1, a control limit of two sigma standard deviations C2, and a control limit of the three sigma standard deviations C3 obtained by calculated statistics. The manufacturing process is regarded as being an “out of control” process if the visualized point K is outside of the control limit of the third sigma standard deviations C3. The manufacturing process is regarded as being an “under control” process if the visualized point K is inside of the control limit control limit of the third sigma standard deviations C3. Among the visualized points K of the “under control process”, the visualized point K shown inside of the control limit of the first sigma standard deviation C1 can represent that the manufacturing process as an excellent process. The visualized point K shown between the control limit of the first sigma standard deviation Cl and the control limit of the third sigma standard deviation C3 can represent that the manufacturing process has slight process parameter variations. As a result, when slight process parameter variations are identified, measures may be immediately taken before the process becomes “out of control”.

Advantages of the embodiments of the invention are described in the following. Process parameters, are in-situ measured and recorded while a wafer is being processed in a manufacturing machine, and transformed into a process summary value. After the wafer has been processed in the manufacturing machine, the wafer is tested for a measured value of the wafer. The wafer measured value and the process summary value can be represented as a visualized point shown on a process control chart having an elliptical control limit and a target position, representing a target (or optimum) wafer measured value of a first (or X) axis and a target (or optimum) process summary value of a second (or Y) axis, placed inside of the control limit. The process quality of the manufacturing machine can be determined according to the relative position of the visualized point and the target point on the process control chart. Thus, a system and method is used to monitor the wafer measured value and the process parameters at the same time. Specifically, a system and method is provided for monitoring a manufacturing process by using the wafer measured value and the process parameters at the same time, so that the relationship between the processes and the manufacturing machines can be monitored, and production yield can be increased. Additionally, because the process parameters are numerous and normally involve manual labor for monitoring, the system and method for monitoring the manufacturing process according to the invention saves time for manual labor and is more efficient. As a result, slight process parameter variations can be immediately identified, so that preventive measures may be taken before the process negatively influences production yield. Additionally, due to the system and method for monitoring the manufacturing process according to the invention, preventative machine maintenance may be performed to decrease product failures, unplanned machine shut downs, and low-yield products or scrap. Manufacturing machine end-product quality is thus improved, without being negatively influenced by shifting process parameters of the manufacturing machine.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A system for monitoring a manufacturing process, comprising:
a two dimensional orthogonal chart with a first axis representing a measured value of a wafer and a second axis representing a process summary value of a manufacturing process of a manufacturing machine, wherein the two dimensional orthogonal chart includes a close-loop control limit; and
a visualized point displayed on the two dimensional orthogonal chart, representing the wafer measured value and the process summary value.

2. The system for monitoring the manufacturing process as claimed in claim 1, wherein the method for determining the wafer measured value and the process summary value comprises:
providing a wafer and in-situ measuring and recording process parameters of a manufacturing machine, wherein if the wafer is processed in the manufacturing machine;
measuring the wafer measured value of the wafer after the wafer has been processed in the manufacturing machine; and
transforming the process parameters into a process summary value.

3. The system for monitoring the manufacturing process as claimed in claim 2, wherein the wafer measured value includes particle numbers, electric properties, flatness, etching rates, thickness, and/or dosages.

4. The system for monitoring the manufacturing process as claimed in claim 2, wherein the process parameters include temperatures, pressure, flow rates, leakage rates, concentrations, and/or time.

5. The system for monitoring the manufacturing process as claimed in claim 1, wherein the close-loop control limit includes an elliptical control limit.

6. The system for monitoring the manufacturing process as claimed in claim 1, wherein the close-loop control limit is determined from the wafer measured value and process summary value statistics obtained from previous manufacturing processes of the manufacturing machine.

7. The system for monitoring the manufacturing process as claimed in claim 1, wherein a process quality of the manufacturing machine is determined according to a position of the visualized point on the two dimensional orthogonal chart.

8. The system for monitoring the manufacturing process as claimed in claim 7, wherein the manufacturing process is regarded as being an “under control” process if the visualized point is inside of the control limit, and the manufacturing process is regarded as being an “out of control” process if the visualized point is outside of the control limit.

9. A method for monitoring a manufacturing process, including:
providing a wafer;
in-situ measuring and recording process parameters of a manufacturing machine if the wafer is processed in the manufacturing machine;
measuring the wafer measured value of the wafer after the wafer has been processed;
transforming the process parameters into a process summary value;
providing a two dimensional orthogonal chart with a first axis representing the wafer measured value and a second axis representing the process summary value, wherein the two dimensional orthogonal chart includes a close-loop control limit; and
displaying a visualized point representing the wafer measured value and the process summary value on the two dimensional orthogonal chart.

10. The method for monitoring the manufacturing process as claimed in claim 9, wherein the close-loop control limit includes an elliptical control limit.

11. The method for monitoring the manufacturing process as claimed in claim 9, wherein the wafer measured value includes particle numbers, electric properties, flatness, etching rates, thickness, and/or dosages.

12. The method for monitoring the manufacturing process as claimed in claim 9, wherein the process parameters include temperatures, pressure, flow rates, leakage rates, concentrations, and/or time.

13. The method for monitoring the manufacturing process as claimed in claim 9, wherein the close-loop control limit is determined from the optimum wafer measured value and process summary value statistics obtained from previous manufacturing processes of the manufacturing machine.

14. The method for monitoring the manufacturing process as claimed in claim 9, wherein a process quality is determined according to a position of the visualized point on the two dimensional orthogonal chart.

15. The method for monitoring the manufacturing process as claimed in claim 14, wherein the manufacturing process is regarded as being an “under control” process if the visualized point is inside of the control limit, and the manufacturing process is regarded as being an “out of control” process if the visualized point is outside of the control limit.

16. A method for monitoring a manufacturing process, including:
providing a wafer;
in-situ measuring and recording process parameters of a manufacturing machine if the wafer is processed in the manufacturing machine;
measuring the wafer for a wafer measured value of the wafer after the wafer has been processed;
transforming the process parameters into a process summary value.
providing a two dimensional orthogonal chart with a first axis representing the wafer measured value and a second axis representing the process summary value, wherein the two dimensional orthogonal chart includes an elliptical control limit determined from the optimum wafer measured value and process summary value statistics obtained from previous manufacturing processes of the manufacturing machine; and
displaying a visualized point representing the wafer measured value and the process summary value on the two dimensional orthogonal chart.

17. The method for monitoring the manufacturing process as claimed in claim 16, wherein the wafer measured value includes particle numbers, electric properties, flatness, etching rates, thickness, and/or dosages.

18. The method for monitoring the manufacturing process as claimed in claim 16, wherein the process parameters include temperatures, pressure, flow rates, leakage rates, concentrations, and/or time.

19. The method for monitoring the manufacturing process as claimed in claim 16, wherein a process quality is determined according to a position of the visualized point on the two dimensional orthogonal chart.

20. The method for monitoring the manufacturing process as claimed in claim 19, wherein the manufacturing process is regarded as being an “under control” process if the visualized point is inside of the control limit, and the manufacturing process is regarded as being an “out of control” process if the visualized point is outside of the control limit.
